(19) United States
(12) Patent Application Publication
(10) Pub. No.: US 2026/0247687 A1
(43) Pub. Date: Aug. 20, 2026

(54) ISOLATION STRUCTURE FOR SEMICONDUCTOR DEVICES

(71) Applicants: TSMC Nanjing Company Limited, Nanjing (CN); TAIWAN SEMICONDUCTOR MANUFACTURING COMPANY, LTD., Hsinchu (TW)

(72) Inventors: Hang XUE, Nanjing City (CN); I-Chih CHEN, Tainan City (TW); Chao-Jui WANG, Hsinchu County (TW)

(73) Assignees: TSMC Nanjing Company Limited, Nanjing (CN); TAIWAN SEMICONDUCTOR MANUFACTURING COMPANY, LTD., Hsinchu (TW)

(21) Appl. No.: 19/073,885

(22) Filed: Mar. 7, 2025

(30) Foreign Application Priority Data
Feb. 20, 2025 (CN) 202520273954.3

(51) Int. Cl. H10D 84/01; H10D 84/83

(52) U.S. Cl. CPC H10D 84/0151; H10D 84/0158; H10D 84/834

(57) ABSTRACT

A method includes following steps. A first semiconductor fin and a second semiconductor fin are formed over a substrate. An isolation region is formed laterally surrounding a lower portion of the first semiconductor fin and a lower portion of the second semiconductor fin. A first polysilicon structure is formed across the first semiconductor fin, a second polysilicon structure is formed across the second semiconductor fin, and a third polysilicon structure is formed over the isolation region. The first polysilicon structure and the second polysilicon structure are removed to form a first gate trench over the first semiconductor fin and a second gate trench over the second semiconductor fin, while leaving the third polysilicon structure over the isolation region. A first gate structure is formed in the first gate trench and a second gate structure formed in the second gate trench.

### PRIORITY CLAIM AND CROSS-REFERENCE

The present application claims priority to China Application Serial Number 202520273954.3, filed Feb. 20, 2025, which is herein incorporated by reference.

### BACKGROUND

Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a FinFET in a three-dimensional view.

FIGS. 2, 4A, 5A, and 10A illustrate cross-sectional views of intermediate stages in the manufacturing of FinFETs in accordance with some exemplary embodiments, which correspond to reference cross-section A-A illustrated in FIG. 1.

FIG. 3 illustrates a perspective view of an intermediate stage in the manufacturing of FinFETs in accordance with some exemplary embodiments.

FIGS. 4B, 5B, 6-9 and 10B illustrate cross-sectional views of intermediate stages in the manufacturing of FinFETs in accordance with some exemplary embodiments, which correspond to reference cross-section B-B illustrated in FIG. 1.

FIGS. 5C and 10C illustrates top views of intermediate stages in the manufacturing of FinFETs in accordance with some exemplary embodiments.

FIGS. 11-16A illustrate cross-sectional views of intermediate stages in the manufacturing of FinFETs in accordance with some exemplary embodiments, which correspond to reference cross-section A-A illustrated in FIG. 1.

FIG. 16B illustrates a top view of an intermediate stage in the manufacturing of FinFETs in accordance with some exemplary embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

With continuous scaling down of the dimensions, semiconductor devices are placed in increasingly closer proximity and higher density, resulting in increased coupling effect between adjacent semiconductor devices in abutted active regions. The abutted active regions can be abutted well regions or abutted standard cells. The increased coupling effect results in significant noise increases, signal delays, logic errors, and even integrated circuit (IC) malfunctions. Isolation of the adjacent semiconductor devices (e.g., FinFETs) in abutted active regions can help prevent the coupling effect, thereby improving IC performance.

The adjacent semiconductor devices in abutted active regions can be isolated by an isolation structure aligned with a middle line between the abutted active regions to reduce the coupling effect. In some embodiments, a continuous poly on oxide definition edge (CPODE) region can be used to form the isolation structure. The term “oxide definition” can define an active region located adjacent to the isolation structure. In some embodiments, the isolation structure can include a dummy metal gate structure that is formed together with metal gate structures in subsequent gate replacement processes. However, this isolation structure presents certain challenges. The dummy metal gate structure of the isolation structure is located close to source/drain (S/D) regions of adjacent semiconductor devices. During the gate replacement process, particularly during the etching step to remove sacrificial polysilicon gates, there is a risk of over-etching. This over-etching can cause the dummy metal gate structure to extrude into the S/D regions. The risk is heightened within the CPODE region at the interface between the shallow trench isolation (STI) region and a gate spacer, increasing the likelihood of dummy metal gate extrusion.

To address this issue, the present disclosure in various embodiments provides an additional photolithographic step to prevent the removal of the dummy polysilicon material in the CPODE region during the gate replacement process. By retaining the dummy polysilicon material in the CPODE region, the issue of dummy metal gate extrusion on the CPODE region is mitigated, thereby improving the over yield.

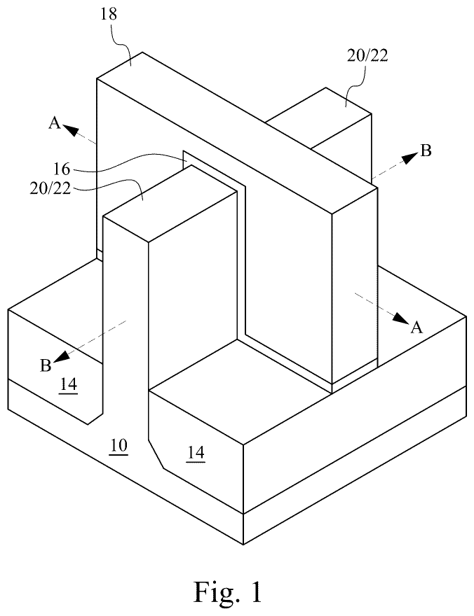

FIG. 1 illustrates an example of a FinFET in a three-dimensional view, in accordance with some embodiments. The FinFET comprises a fin 12 on a substrate 10 (e.g., a semiconductor substrate). Isolation regions 14 are disposed in the substrate 10, and the fin 12 protrudes above and from between neighboring isolation regions 14. Although the isolation regions 14 are described/illustrated as being separate from the substrate 10, as used herein the term “substrate” may be used to refer to just the semiconductor substrate or a semiconductor substrate inclusive of isolation regions. Additionally, although the fin 12 is illustrated as a single, continuous material as the substrate 10, the fin 12 and/or the substrate 10 may comprise a single material or a plurality of materials. In this context, the fin 12 refers to the portion extending between the neighboring isolation regions 14.

A gate dielectric layer 16 is along sidewalls and over a top surface of the fin 12, and a gate electrode 18 is over the gate dielectric layer 16. Source/drain regions 20 or 22 are disposed in opposite sides of the fin 12 with respect to the gate dielectric layer 16 and gate electrode 18. FIG. 1 further illustrates reference cross-sections that can be used in later figures. Cross-section A-A is along a longitudinal axis of the gate electrode 18 and in a direction, for example, perpendicular to the direction of current flow between the source/drain regions 20/22 of the FinFET. Cross-section B-B is perpendicular to cross-section A-A and is along a longitudinal axis of the fin 12 and in a direction of, for example, a current flow between the source/drain regions 20/22 of the FinFET. Subsequent figures refer to these reference cross-sections for clarity.

Some embodiments discussed herein are discussed in the context of FinFETs formed using a gate-last process. In other embodiments, a gate-first process may be used. Also, some embodiments contemplate aspects used in planar devices, such as planar FETs, nanostructure (e.g., nanosheet, nanowire, gate-all-around, or the like) field effect transistors (NSFETs), or the like.

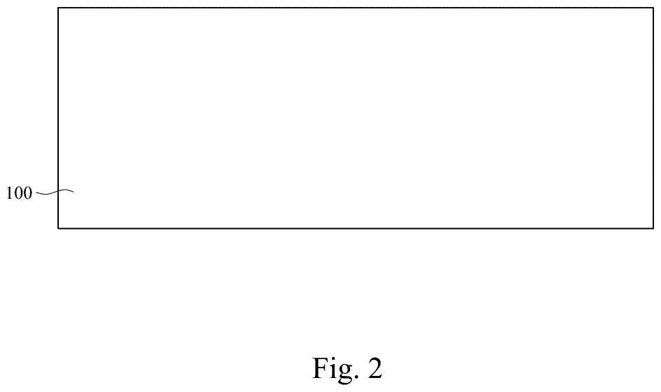

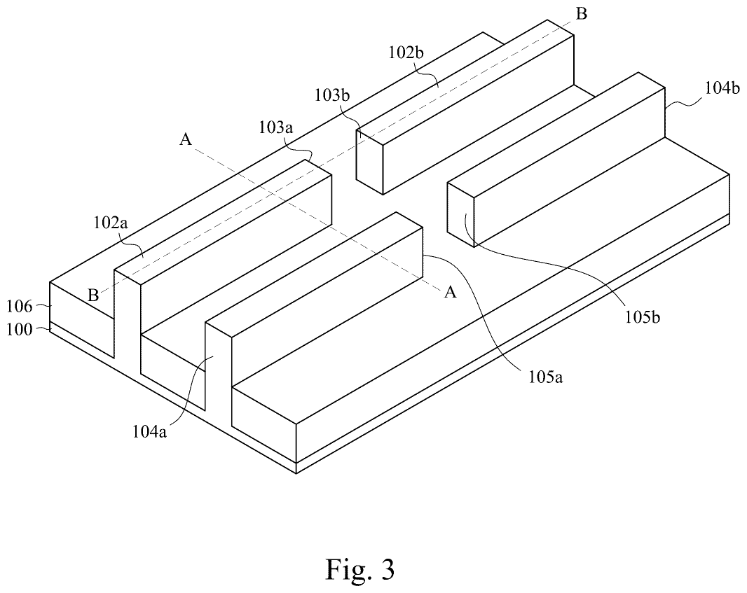

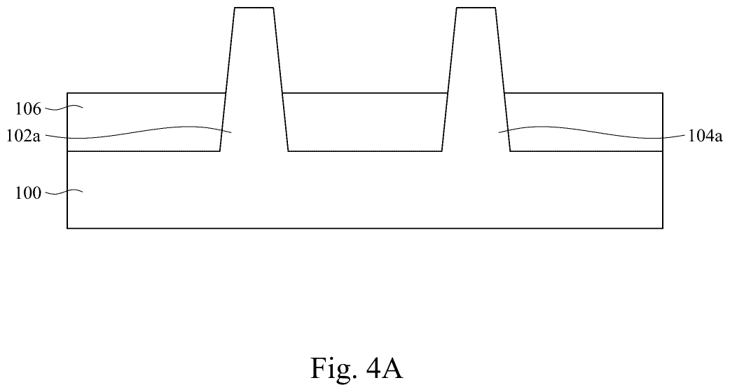

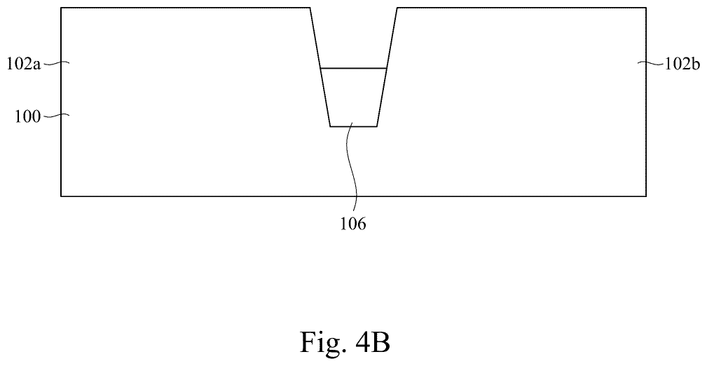

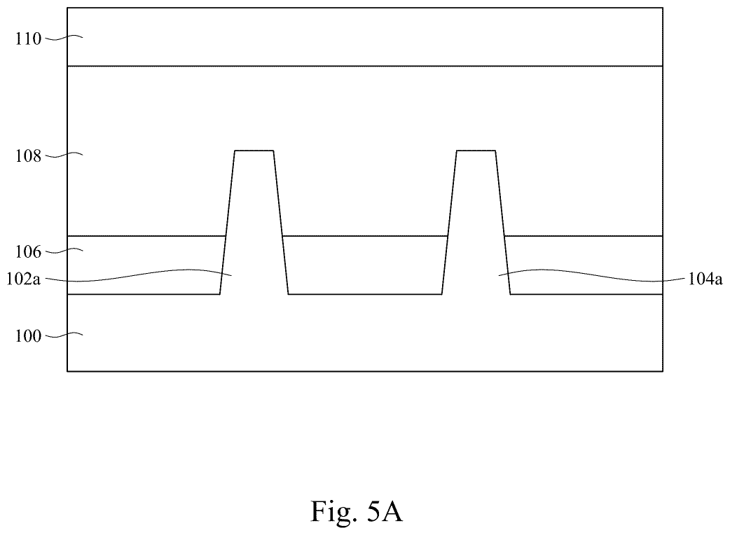

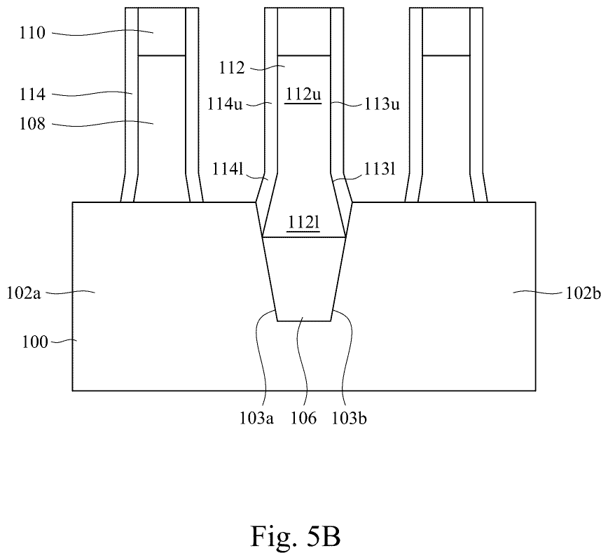

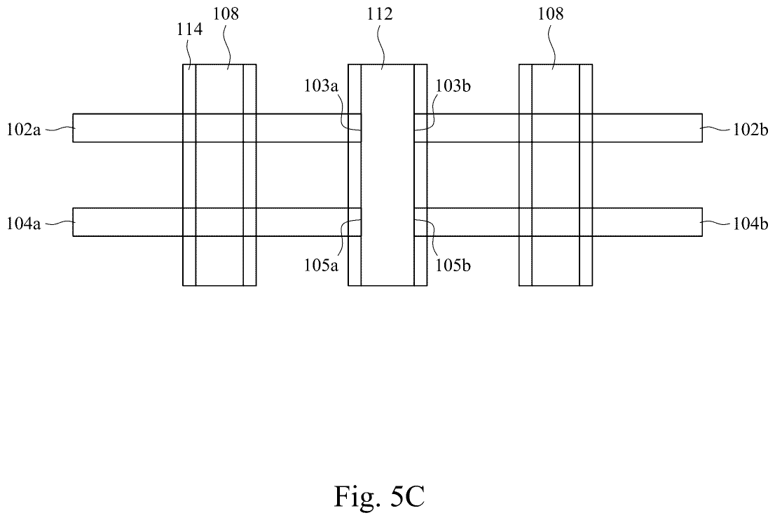

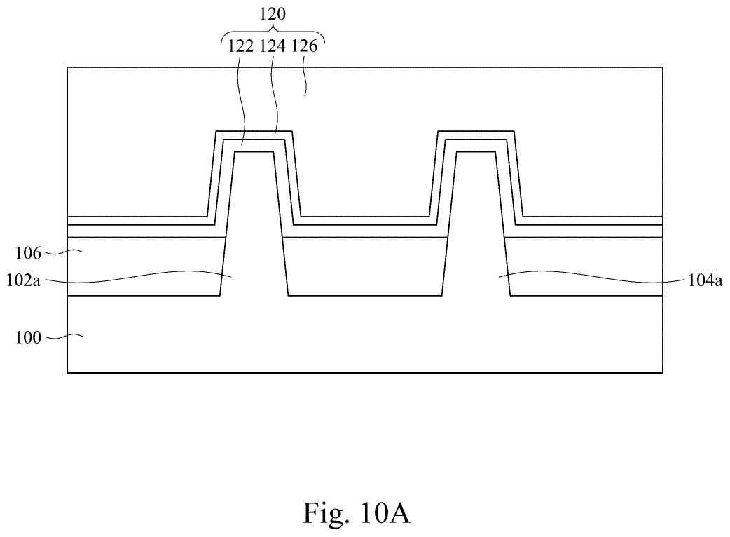

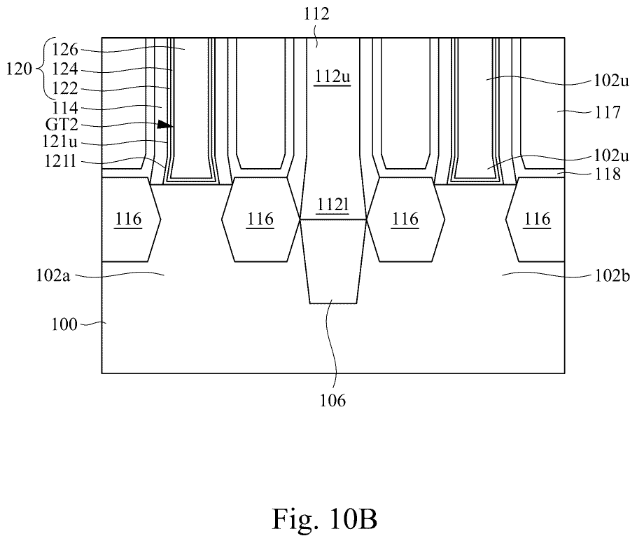

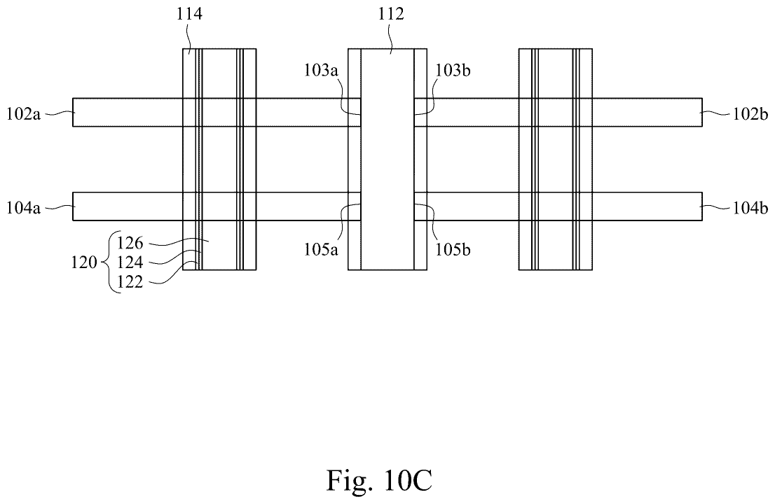

FIGS. 2 through 10C illustrate cross-sectional views, a perspective view and a top view of intermediate stages in the manufacturing of FinFETs in accordance with some exemplary embodiments. FIGS. 2, 4A, 5A, and 10A illustrate reference cross-section A-A illustrated in FIG. 1, except for multiple fins. FIG. 3 illustrates a perspective view of multiple fins. FIGS. 4B, 5B, 6-9 and 10B illustrate reference cross-section B-B illustrated in FIG. 1, except for multiple FinFETs in abutted active regions. FIGS. 5C and 10C illustrates top views of multiple FinFETs. Throughout the various views and illustrative embodiments, like reference numbers are used to designate like elements. It is understood that additional operations can be provided before, during, and after the processes shown by FIGS. 2-10C, and some of the operations described below can be replaced or eliminated, for additional embodiments of the method. The order of the operations/processes may be interchangeable.

FIG. 2 illustrates a perspective view of an initial structure. The initial structure includes a substrate 100. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

FIG. 3 is a perspective view illustrating the formation of fins 102a, 102b, 104a, 104b and isolation regions 106 between neighboring fins. FIG. 4A is a cross-sectional view taken along the cross-section A-A in FIG. 3. FIG. 4B is a cross-sectional view taken along the cross-section B-B in FIG. 3. In FIGS. 3-4B, fins 102a, 102b, 104a, 104b are formed in the substrate 100. In some embodiments, the fins 102a, 102b, 104a, 104b may be formed in the substrate 100 by etching trenches in the substrate 100. The etching may be any acceptable etch process, such as a reactive ion etch (RIE), neutral beam etch (NBE), the like, or a combination thereof. The etch may be anisotropic.

The fins may be patterned by any suitable method. For example, the fins 102a, 102b, 104a, and 104b may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. In some embodiments, the mask (or other layer) may remain on the fins 102a, 102b, 104a, and 104b.

In some embodiments, a longitudinal axis of the fin 102a is aligned with a longitudinal axis of the fin 102b, and a longitudinal axis of the fin 104a is aligned with a longitudinal axis of the fin 104b. In some embodiments, the fins 102a and 104a are included in first well region or a first standard cell, the fins 102b and 104b are included in a second well region or a second standard cell abutting the first well region or the first standard cell. A longitudinal end 103a of the fin 102a is spaced apart from a longitudinal end 103b of the fin 102b by a portion of the STI region 106, which will be covered with a continuous poly on oxide definition edge (CPODE) structure extending in a direction perpendicular to the fins 102a, 102b, 104a, and 104b in subsequent processing. A longitudinal end 105a of the fin 104a is spaced apart from a longitudinal end 105b of the fin 104b by a portion of the STI region 106, which will be covered with the (CPODE) structure in subsequent processing.

Once the fins 102a, 102b, 104a, and 104b are formed, isolation regions 106 are formed over the substrate 100 to laterally surround lower portions of the fins 102a, 102b, 104a, and 104b. In some embodiments, the isolation regions 106 are formed from an insulation material, such as silicon oxide, a nitride, the like, or a combination thereof. The insulation material may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials formed by any acceptable process may be used. In the illustrated embodiment, the insulation material of the isolation regions 106 is silicon oxide formed by a FCVD process. An anneal process may be performed once the insulation material is formed. Although the insulation material of the isolation regions 106 is illustrated as a single layer, some embodiments may utilize multiple layers. For example, in some embodiments a liner (not shown) may first be formed along a surface of the substrate 100 and the fins 102a, 102b, 104a, and 104b. Thereafter, a fill material, such as those discussed above may be formed over the liner.

Once the insulation material of the isolation regions 106 is deposited over the fins 102a, 102b, 104a, and 104b, a removal process is applied to the insulation material to remove excess insulation material over the fins 102a, 102b, 104a, and 104b. In some embodiments, a planarization process such as a chemical mechanical polish (CMP), an etch-back process, combinations thereof, or the like may be utilized. The planarization process exposes the fins 102a, 102b, 104a, and 104b such that top surfaces of the fins 102a, 102b, 104a, and 104b and the insulation material are level after the planarization process is complete. In embodiments in which a mask remains on the fins 102a, 102b, 104a, and 104b, the planarization process may expose the mask or remove the mask such that top surfaces of the mask or the fins 102a, 102b, 104a, and 104b, respectively, and the insulation material are level after the planarization process is complete.

Afterwards, the insulation material is recessed to form shallow trench isolation (STI) regions 106. The insulation material is recessed such that upper portions of fins 102a, 102b, 104a, and 104b protrude from between neighboring STI regions 106. Further, the top surfaces of the STI regions 106 may have a flat surface as illustrated, a convex surface, a concave surface (such as dishing), or combinations thereof. The top surfaces of the STI regions 106 may be formed flat, convex, and/or concave by an appropriate etch. The STI regions 106 may be recessed using an acceptable etching process, such as one that is selective to the material of the STI regions 106 (e.g., etches the insulation material at a faster rate than the semiconductor material of the fins 102a, 102b, 104a, and 104b). For example, an oxide removal using, for example, dilute hydrofluoric (dHF) acid may be used.

The process described with respect to FIGS. 2-3 is just one example of how the fins 102a, 102b, 104a, and 104b may be formed. In some embodiments, the fins 102a, 102b, 104a, and 104b may be formed by an epitaxial growth process. For example, a dielectric layer can be formed over a top surface of the substrate 100, and trenches can be etched through the dielectric layer to expose the underlying substrate 100. Homoepitaxial structures can be epitaxially grown in the trenches, and the dielectric layer can be recessed such that the homoepitaxial structures protrude from the dielectric layer to form fins. Additionally, in some embodiments, heteroepitaxial structures can be used for the fins. For example, the fins 102a, 102b, 104a, and 104b in FIG. 3 can be recessed, and a material different from the fins 102a, 102b, 104a, and 104b may be epitaxially grown over the recessed fins 102a, 102b, 104a, and 104b. In such embodiments, the fins comprise the recessed material as well as the epitaxially grown material disposed over the recessed material. In an even further embodiment, a dielectric layer can be formed over a top surface of the substrate 100, and trenches can be etched through the dielectric layer. Heteroepitaxial structures can then be epitaxially grown in the trenches using a material different from the substrate 100, and the dielectric layer can be recessed such that the heteroepitaxial structures protrude from the dielectric layer to form the fins. In some embodiments where homoepitaxial or heteroepitaxial structures are epitaxially grown, the epitaxially grown materials may be in-situ doped during growth, which may obviate prior and subsequent implantations although in situ and implantation doping may be used together.

Still further, it may be advantageous to epitaxially grow a material in an NFET region different from the material in a PFET. In various embodiments, upper portions of the fins 102a, 102b, 104a, and 104b may be formed from silicon-germanium (SiₓGe₁₋ₓ, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

Although not specifically illustrated, appropriate wells may be formed in the fins 102a, 102b, 104a, and 104b and/or substrate 100. For example, an n-well may be formed in a PFET region encompassing the fins 102a and 104a of the substrate 100 where p-type devices, such as p-type FinFETs, are to be formed, and a p-well may be formed in an NFET region encompassing the fins 102b and 104b of the substrate 100 where n-type devices, such as n-type FinFETs, are to be formed.

In FIGS. 5A and 5B, a sacrificial gate layer is formed on the fins 102a, 102b, 104a and 104b by, for example, depositing a sacrificial material over the fins 102a, 102b, 104a and 104b, followed by planarizing sacrificial material, such as by a CMP. The sacrificial gate layer may be amorphous silicon, polycrystalline-silicon (polysilicon), poly-crystalline silicon-germanium (poly-SiGe), metallic nitrides, metallic silicides, metallic oxides, and metals. The sacrificial gate layer may be deposited by physical vapor deposition (PVD), CVD, sputter deposition, or other techniques for depositing the selected material. The sacrificial gate layer may be made of other materials that have a high etching selectivity from the etching of isolation regions, e.g., the STI regions 106. In some embodiments, the sacrificial gate layer may include a semiconductor material such as polysilicon.

In some embodiments, a patterned mask 110 is formed over the sacrificial gate layer to aid in the patterning. In some embodiments, the patterned mask 110 is made of one or more layers of SiO₂, SiCN, SiON, Al₂O₃, SiN, or other suitable materials. By using the patterned mask 110 as an etching mask, the sacrificial gate layer is patterned into a plurality of separate sacrificial gate structures 108 extending across channel regions of the fins 102a, 102b, 104a and 104b, and a CPODE isolation structure 112 extending over the isolation region 106. The sacrificial gate structures 108 and the CPODE isolation structure 112 may have longitudinal axes substantially perpendicular to the longitudinal axes of fins 102a, 102b, 104a and 104b.

Different from the sacrificial gate structures 108, the CPODE isolation structure 112 serves as an isolation structure for isolating the neighboring fins (e.g., fins 102a and 102b) and thus does not extend across any of fins. In some embodiments, the CPODE isolation structure 112 has a bottom surface entirely in contact with the isolation region. In particular, as illustrated in the top view of FIG. 5C, the CPODE isolation structure 112 is localized between the longitudinal ends 103a/103b of the fins 102a/102b, and between the longitudinal ends 105a/105b of the fins 104a/104b. In this way, the CPODE isolation structure 112 can serve to isolate the FinFETs formed in the fins 102a/104a from the FinFETs formed in the fins 102b/104b.

As illustrated in FIG. 5B, in some embodiments, the sacrificial gate structures 108 and the CPODE isolation structures 112 each have a nonlinear sidewall profile. In particular, the CPODE isolation structure 112 has an upper portion 112u and a lower portion 112l having different cross-sectional profiles, and the sacrificial gate structures 108 each have an upper portion 108u and a lower portion 108l having different cross-sectional profiles. The lower portions 108l and 112l have a width decreasing as a distance from the substrate 100 increases. The upper portions 108u and 112u have a width remaining substantially constant as a distance from the substrate 100 increases.

The CPODE isolation structure 112 thus has an upper sidewall 113u and a lower sidewall 113l angled from the upper sidewall 113u. The nonlinear sidewall profile of the sacrificial gate structures 108 and the CPODE isolation structures 112 is primarily formed due to the anisotropic nature of the etching step employed during their fabrication. In particular, the CPODE isolation structure 112 exhibits a distinct upper portion 112u and lower portion 112l due to the etching chemistry and conditions. The upper portion 112u extends substantially vertically because the etching process is more anisotropic in this region, favoring vertical etching over lateral etching. This results in a sidewall profile where the width remains substantially constant as the distance from the substrate 100 increases. Conversely, the lower portion 112l of the CPODE isolation structure 112 experiences a different etching dynamic. As the etching progresses deeper into the polysilicon material, the etch rate may vary due to factors such as changes in etchant concentration, ion bombardment energy and angle, and the presence of by-products that can passivate certain surfaces. These factors contribute to a reduction in the etch rate in the lateral direction, causing the width of the lower portion 112l to decrease with increasing distance from the substrate 100. This results in a tapered profile where the lower sidewall 113l is angled relative to the upper sidewall 113u.

After forming the sacrificial gate structures 108 and the CPODE isolation structure 112, gate spacers 114 formed on sidewalls of the sacrificial gate structures 108 and the CPODE isolation structure 112. In some embodiments of the gate spacer formation step, a spacer material layer is deposited on the substrate 100. The spacer material layer may be a conformal layer that is subsequently etched back to form gate spacers 114. By way of example and not limitation, the spacer material(s) may be formed by depositing dielectric material(s) over the sacrificial gate structures 108 and the CPODE isolation structure 112 using suitable deposition processes such as, CVD process, a subatmospheric CVD (SACVD) process, a flowable CVD process, an ALD process, a PVD process, or other suitable process. An anisotropic etching process is then performed on the deposited dielectric material(s) to expose portions of the fins 102a, 102b, 104a, and 104b not covered by the sacrificial gate structures 108 (e.g., in source/drain regions of the fins 102a, 102b, 104a, and 104b. Portions of the spacer layer 114 directly above the sacrificial gate structures 108 and CPODE isolation structure 112 may be completely removed by this anisotropic etching process. Portions of the spacer layer 114 on sidewalls of the sacrificial gate structures 108 and the CPODE isolation structure 112 may remain, forming gate sidewall spacers, which are denoted as the gate spacers 114, for the sake of simplicity.

In some embodiments, as illustrated in FIG. 5B, the gate spacers 114 each have an upper portion 114u and a lower portion 114l angled from the upper portion 114u. This is due to that the gate spacers 114 are conformal to the nonlinear sidewalls of the sacrificial gate structures 108 and CPODE isolation structure 112.

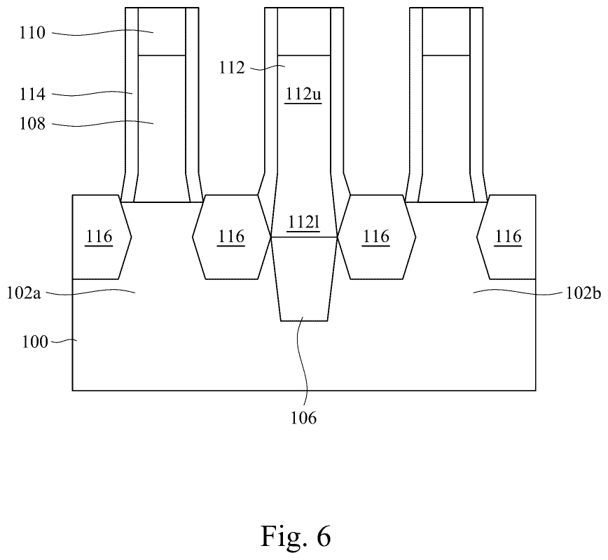

In FIG. 6, after formation of the gate spacers 114 is completed, source/drain epitaxial structures 116 are formed on source/drain regions of the fins 102a, 102b, 104a, and 104b that are not covered by the sacrificial gate structures 108 and the gate spacers 114. In some embodiments, formation of the source/drain epitaxial structures 116 includes recessing source/drain regions of the fins 102a, 102b, 104a, and 104b, followed by epitaxially growing semiconductor materials in the recessed source/drain regions of the fins 102a, 102b, 104a, and 104b.

The source/drain regions of the fins 102a, 102b, 104a, and 104b can be recessed using suitable selective etching processing that attacks the semiconductor fins 102a, 102b, 104a, and 104b, but hardly attacks the gate spacers 114 and the patterned mask 110. For example, recessing the semiconductor fins 102a, 102b, 104a, and 104b may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the semiconductor fins 102a, 102b, 104a, and 104b at a faster etch rate than it etches the gate spacers 114 and the mask 110. In some other embodiments, recessing the semiconductor fins 102a, 102b, 104a, and 104b may be performed by a wet chemical etch, such as ammonium peroxide mixture (APM), NH₄OH, tetramethylammonium hydroxide (TMAH), combinations thereof, or the like, which etches the semiconductor fins 102a, 102b, 104a, and 104b at a faster etch rate than it etches the gate spacers 114 and the mask 110. In some other embodiments, recessing the semiconductor fins 102a, 102b, 104a, and 104b may be performed by a combination of a dry chemical etch and a wet chemical etch.

Once recesses are created in the source/drain regions of the fins 102a, 102b, 104a, and 104b, source/drain epitaxial structures 116 are formed in the source/drain recesses in the fins 102a, 102b, 104a, and 104b by using one or more epitaxy or epitaxial (epi) processes that provides one or more epitaxial materials on the semiconductor fin 104. During the epitaxial growth process, the gate spacers 114 limit the one or more epitaxial materials to source/drain regions in the fins 102a, 102b, 104a, and 104b. In some embodiments, the lattice constants of the epitaxial structures 116 are different from the lattice constant of the semiconductor fins 102a, 102b, 104a, and 104b, so that the channel region in the fins 102a, 102b, 104a, and 104b and between the epitaxial structures 116 can be strained or stressed by the epitaxial structures 116 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor fins 102a, 102b, 104a, and 104b. In some embodiments, the epitaxial structures 116 may have surfaces raised from respective outer surfaces of the fins 102a, 102b, 104a, 104b, and may have facets.

In some embodiments, the source/drain epitaxial structures 116 may include Ge, Si, GaAs, AlGaAs, SiGe, GaAsP, SiP, or other suitable material. The source/drain epitaxial structures 116 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 116 are not in-situ doped, an implantation process (i.e., a junction implant process) is performed to dope the source/drain epitaxial structures 116. In some exemplary embodiments, the source/drain epitaxial structures 116 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 102a, 102b, 104a and/or 104b in the p-type device regions. The mask may then be removed. Subsequently, a mask, such as a photoresist, may be formed over the p-type device region while exposing the n-type device regions, and n-type epitaxial structures may be formed on the exposed fins 102a, 102b, 104a and/or 104b in the n-type device region. The mask may then be removed.

Once the source/drain epitaxial structures 116 are formed, an annealing process can be performed to activate the p-type dopants or n-type dopants in the source/drain epitaxial structures 116. The annealing process may be, for example, a rapid thermal anneal (RTA), a laser anneal, a millisecond thermal annealing (MSA) process or the like.

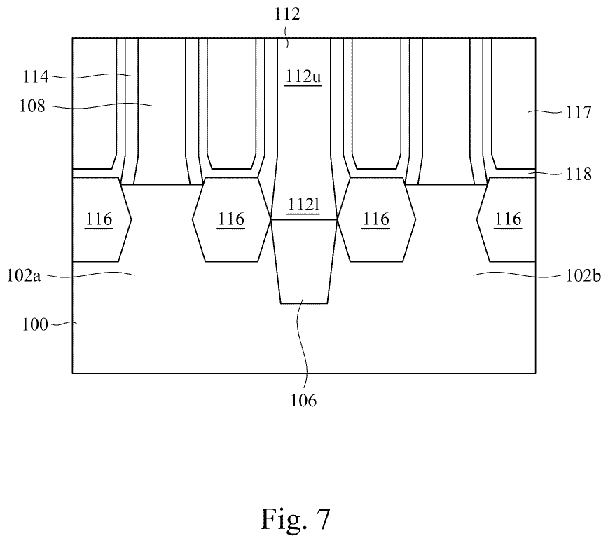

Next, in FIG. 7, an interlayer dielectric (ILD) layer 117 is formed on the substrate 100. In some embodiments, a contact etch stop layer (CESL) 118 is optionally formed prior to forming the ILD layer 117. In some examples, the CESL 118 includes a silicon nitride layer, silicon oxide layer, a silicon oxynitride layer, and/or other suitable materials having a different etch selectivity than the ILD layer 117. The CESL 118 may be formed by plasma-enhanced chemical vapor deposition (PECVD) process and/or other suitable deposition or oxidation processes. In some embodiments, the ILD layer 117 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. The ILD layer 117 may be deposited by a PECVD process or other suitable deposition technique. In some embodiments, after formation of the ILD layer 117, the wafer may be subject to a high thermal budget process to anneal the ILD layer 117.

In some examples, after forming the ILD layer 117, a planarization process may be performed to remove excessive materials of the ILD layer 117. For example, a planarization process includes a chemical mechanical planarization (CMP) process which removes portions of the ILD layer 117 (and CESL 118, if present) overlying the sacrificial gate structures 108 and the CPODE isolation structure 112. In some embodiments, the CMP process also removes patterned mask 110 (as shown in FIG. 7) and exposes the sacrificial gate structures 108 and the CPODE isolation structure 112.

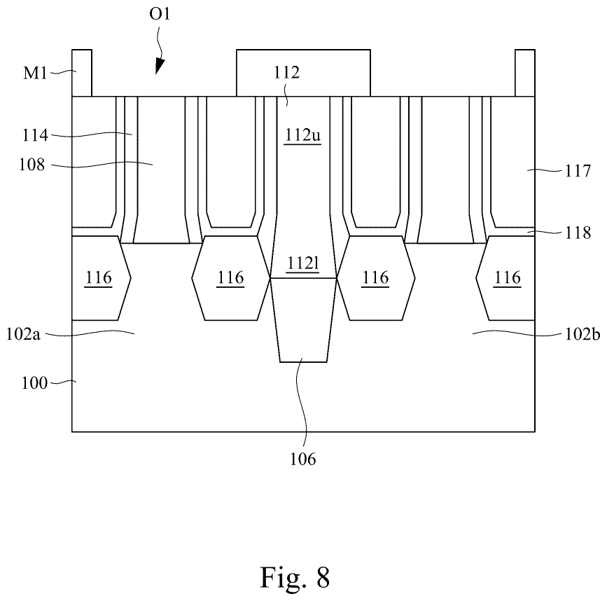

In FIG. 8, a patterned mask layer M1 is formed over the ILD layer 117 to define locations of target polysilicon regions that would be removed in subsequent gate replacement processing. The patterned mask layer M1 may comprise an organic material, such as a photoresist material, and may be formed using a spin-on coating process, followed by patterning the photoresist material, using suitable lithography techniques, to forming one or more openings O1 extending through the patterned mask layer M1 to expose the sacrificial gate structures 108, but not exposing the CPODE isolation structure 112. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

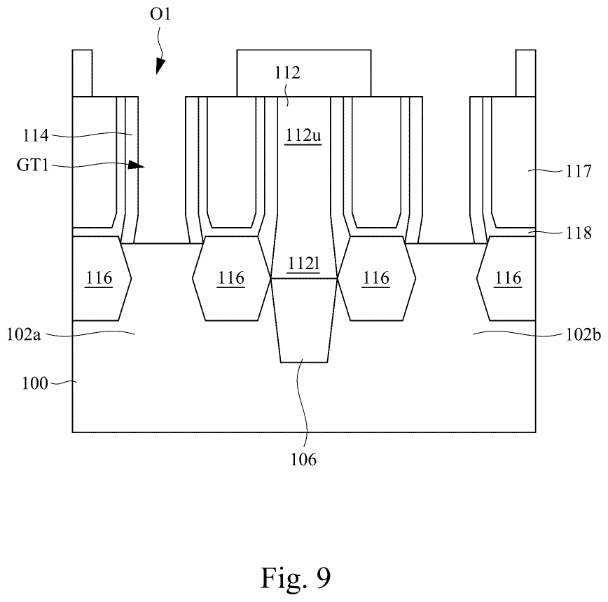

Next, in FIG. 9, with the patterned mask M1 in place, the exposed sacrificial gate structures 108 are removed by one or more etching processes using the patterned mask M1 as an etch mask, resulting in gate trenches GT1 between corresponding gate spacers 114. The sacrificial gate structures 108 are removed using a selective etching process (e.g., selective dry etching, selective wet etching, or a combination thereof) that etches materials in the sacrificial gate structures 108 at a faster etch rate than it etches other materials (e.g., gate spacers 114 and/or the ILD layer 117). In the absence of the patterned mask M1, the etchant used to remove the polysilicon material of the sacrificial gate structures 108 would also remove the polysilicon material of the CPODE isolation structure 112. This removal would expose the interface region between the STI region 106 and the gate spacers 114, making it more susceptible to damage by the etchant. Such damage could lead to the unintended etching of the gate spacers 114 surrounding the CPODE isolation structure 112. Consequently, when the space left by the removed CPODE isolation structure 112 is filled with a dummy metal gate in subsequent processing, it could result in the dummy metal gate extruding into the source/drain regions. However, since the etching process is performed with the patterned mask M1 covering the CPODE isolation structure 112, the CPODE isolation structure 112 remains protected from the etchant. This effectively mitigates the risk of unintended etching of the gate spacers 114 around the CPODE isolation structure 112, thereby preventing the issue of dummy metal gate extrusion.

After the etching process(es) for forming the gate trenches GT1 are completed, the patterned mask layer M1 is removed, for example, using a plasma ash process. In some embodiments, a plasma ash process is performed such that the temperature of the photoresist mask M1 is increased until the photoresist mask M1 experiences a thermal decomposition and may be removed. However, any other suitable process, such as a wet strip, may be utilized.

Thereafter, replacement gate structures 120 are respectively formed in the gate trenches GT1, as illustrated in FIGS. 10A-10C. The gate structures 120 may be the final gates of FinFETs. The final gate structures each may be a high-k/metal gate (HKMG) stack, however other compositions are possible. In some embodiments, each of the gate structures 120 forms the gate associated with the three-sides of the channel regions provided by the fins 102a, 102b, 104a, and 104b. Stated another way, each of the gate structures 120 wraps around the fins 102a, 102b, 104a, and 104b on three sides. In various embodiments, the high-k/metal gate structure 120 includes a gate dielectric layer 122 lining the gate trench GT1, a work function metal layer 124 formed over the gate dielectric layer 122, and a fill metal 126 formed over the work function metal layer 124 and filling a remainder of gate trenches GT1. The gate dielectric layer 122 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (~3.9). The work function metal layer 124 and/or fill metal layer 126 used within high-k/metal gate structures 120 may include a metal, metal alloy, or metal silicide. Formation of the high-k/metal gate structures 120 may include multiple deposition processes to form various gate materials, one or more liner layers, and one or more CMP processes to remove excessive gate materials.

Because the gate structures 120 are formed in the gate trenches GT1 left by the removed sacrificial gate structures 108, the gate structures 120 inherent the geometry of the removed sacrificial gate structures 108, and thus the gate structures 108 each have a nonlinear sidewall profile. For example, the gate structures 120 each have an upper portion 120u and a lower portion 120l having different cross-sectional profiles. The lower portions 120l have a width decreasing as a distance from the substrate 100 increases. The upper portions 120u have a width remaining substantially constant as a distance from the substrate 100 increases. The gate structure 120 thus has an upper sidewall 121u and a lower sidewall 121l angled from the upper sidewall 121u.

In some embodiments, the interfacial layer of the gate dielectric layer 122 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 122 may include hafnium oxide (HfO₂). Alternatively, the gate dielectric layer 122 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 124 may include work function metals to provide a suitable work function for the high-k/metal gate structures 120. For an n-type FinFET, the work function metal layer 124 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 124 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 126 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

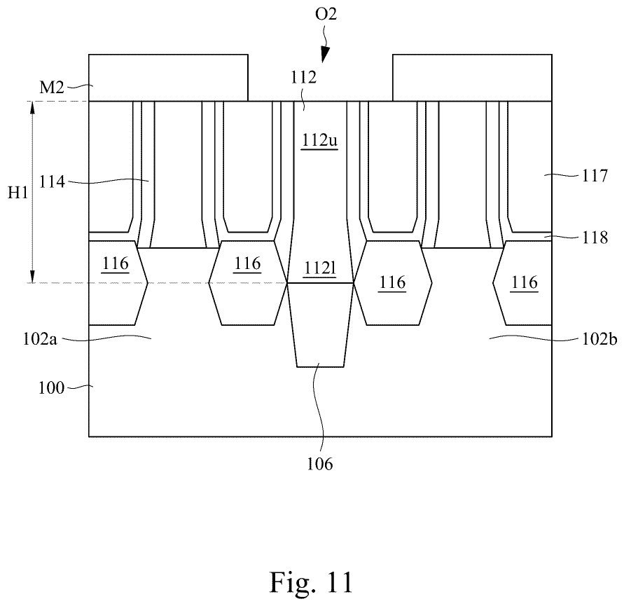

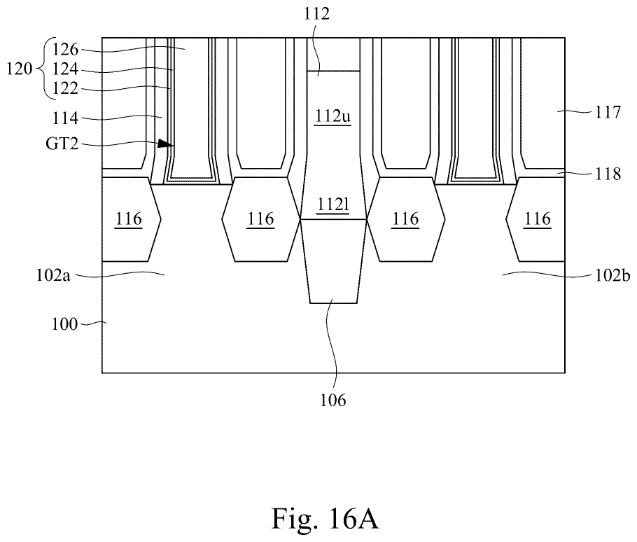

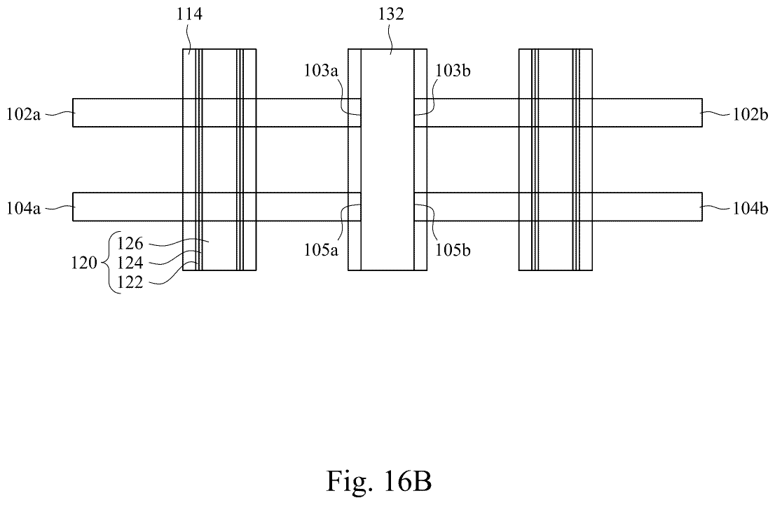

FIGS. 11 through 16B illustrate cross-sectional views and a top view of intermediate stages in the manufacturing of FinFETs in accordance with some exemplary embodiments. FIGS. 11-16A illustrate reference cross-section A-A illustrated in FIG. 1, except for multiple fins. FIG. 16B illustrates a top view of multiple FinFETs. Throughout the various views and illustrative embodiments, like reference numbers are used to designate like elements. It is understood that additional operations can be provided before, during, and after the processes shown by FIGS. 11-16B, and some of the operations described below can be replaced or eliminated, for additional embodiments of the method. The order of the operations/processes may be interchangeable.

FIG. 11 illustrates a similar structure to that shown in FIG. 7, except that a patterned mask layer M2 is formed over the ILD layer 117 to define locations of target polysilicon regions that would be recessed in subsequent gate replacement processing. The patterned mask layer M2 may comprise an organic material, such as a photoresist material, and may be formed using a spin-on coating process, followed by patterning the photoresist material, using suitable lithography techniques, to forming one or more openings O2 extending through the patterned mask layer M2 to expose the CPODE isolation structure 112, but not exposing the sacrificial gate structures 108. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

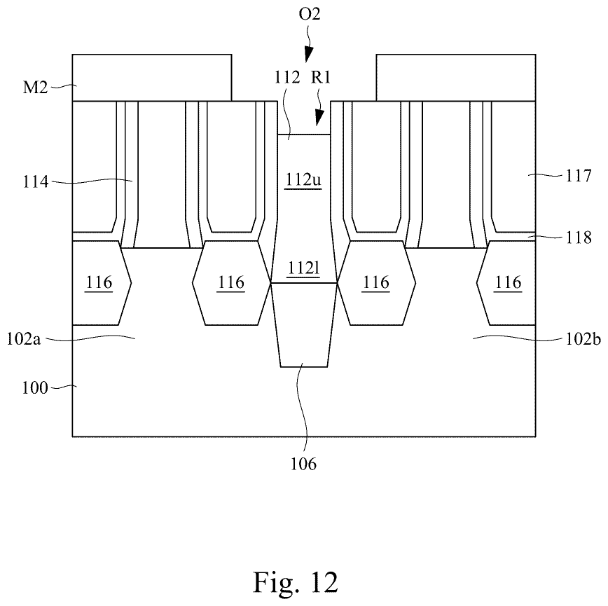

Next, in FIG. 12, with the patterned mask M2 in place, the CPODE isolation structure 112 is recessed by a selective etch back process using the patterned mask M2 as an etch mask, resulting in a CPODE recess R1 between corresponding gate spacers 114. The CPODE isolation structure 112 is recessed using a selective etching process (e.g., selective dry etching, selective wet etching, or a combination thereof) that etches the polysilicon material in the CPODE isolation structure 112 at a faster etch rate than it etches other materials (e.g., gate spacers 114 and/or the ILD layer 117). In some embodiments, the CPODE recess R1 has a depth less than an initial height H1 of the CPODE isolation structure 112 (as shown in FIG. 11). In some embodiments, a ratio of the depth of the CPODE recess R1 to the initial height H1 is in a range from about 0.2 to about 0.8. If the ratio of CPODE recess depth to CPODE initial height is excessively small (e.g., less than 0.2), a protective cap 132 subsequently formed in the CPODE recess R1 may be too thin to safeguard the CPODE isolation structure during a subsequent etching process for removing the sacrificial gate structures 108. If the ratio of CPODE recess depth to CPODE initial height is excessively large (e.g., greater than 0.8), the STI region 106 under the CPODE isolation structure 112 may be inadvertently damaged during forming the CPODE recess R1.

After the etching process for forming the CPODE recess R1 is completed, the patterned mask layer M2 is removed, for example, using a plasma ash process. In some embodiments, a plasma ash process is performed such that the temperature of the photoresist mask M2 is increased until the photoresist mask M2 experiences a thermal decomposition and may be removed. However, any other suitable process, such as a wet strip, may be utilized.

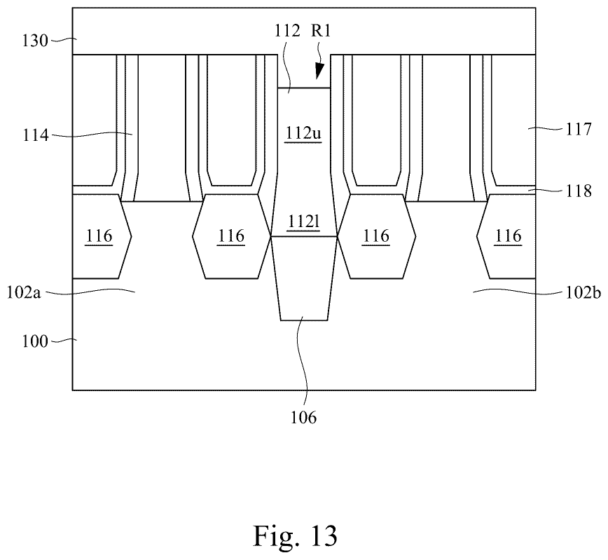

In FIG. 13, a dielectric layer 130 is deposited overfilling the CPODE recess R1 by using suitable deposition techniques, such as ALD or CVD. In some embodiments, the dielectric layer 130 includes materials similar to the ILD layer 117 and different from the polysilicon material of the sacrificial gate structures 108. For example, the dielectric layer 130 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

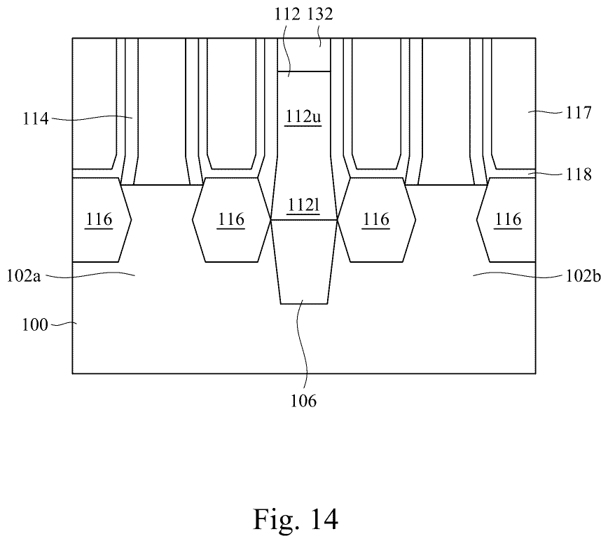

Next, a planarization process such as a chemical mechanical polish (CMP), an etch-back process, combinations thereof, or the like may be performed on the dielectric layer 130 until the sacrificial gate structures 108 get exposed, as illustrated in FIG. 14. The planarization process removes a portion of the dielectric layer 130 outside the CPODE recess R1, while leaving a remaining portion of the dielectric layer 130 in the CPODE recess R1 to serve as a protective cap 132 covering the recessed CPODE isolation structure 112.

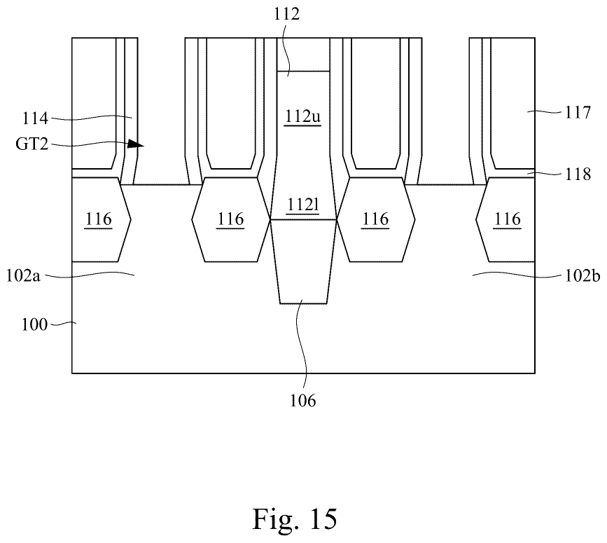

Next, in FIG. 15, with the protective cap 132 covering the CPODE isolation structure 112, the exposed sacrificial gate structures 108 are removed by one or more etching processes. This removal creates gate trenches GT2 between corresponding gate spacers 114. In this embodiment, the removal of the exposed sacrificial gate structures 108 can be accomplished without the need for an additional patterned photoresist as an etch mask. This is because the protective cap 132 effectively shields the CPODE isolation structure 112 from the etching process. In the absence of the protective cap 132, the etchant used to remove the polysilicon material of the sacrificial gate structures 108 would also remove the polysilicon material of the CPODE isolation structure 112. This removal would expose the interface region between the STI region 106 and the gate spacers 114, making it more susceptible to damage by the etchant. Such damage could lead to the unintended etching of the gate spacers 114 surrounding the CPODE isolation structure 112. Consequently, when the space left by the removed CPODE isolation structure 112 is filled with a dummy metal gate in subsequent processing, it could result in the dummy metal gate extruding into the source/drain regions. However, since the etching process is performed with the protective cap 132 covering the CPODE isolation structure 112, the CPODE isolation structure 112 remains protected from the etchant. This effectively mitigates the risk of unintended etching of the gate spacers 114 around the CPODE isolation structure 112, thereby preventing the issue of dummy metal gate extrusion.

Thereafter, replacement gate structures 120 are respectively formed in the gate trenches GT2, as illustrated in FIGS. 16A-16B. The gate structures 120 may be the final gates of FinFETs. The final gate structures each may be a high-k/metal gate (HKMG) stack, however other compositions are possible. In some embodiments, each of the gate structures 120 forms the gate associated with the three-sides of the channel regions provided by the fins 102a, 102b, 104a, and 104b. Example materials, forming methods and other details associated with the replacement gate structures are discussed previously with respect to FIGS. 10A-10C and thus are not repeated for the sake of brevity.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that the issue of dummy metal gate extrusion on the CPODE region is mitigated by retaining the dummy polysilicon material in the CPODE region.

In some embodiments, a method includes following steps. A first semiconductor fin and a second semiconductor fin are formed over a substrate. An isolation region is formed laterally surrounding a lower portion of the first semiconductor fin and a lower portion of the second semiconductor fin. A first polysilicon structure is formed across the first semiconductor fin, a second polysilicon structure is formed across the second semiconductor fin, and a third polysilicon structure is formed over the isolation region. The first polysilicon structure and the second polysilicon structure are removed to form a first gate trench over the first semiconductor fin and a second gate trench over the second semiconductor fin, while leaving the third polysilicon structure over the isolation region. A first gate structure is formed in the first gate trench and a second gate structure formed in the second gate trench. In some embodiments, the method further includes recessing the third polysilicon structure prior to removing the first and second polysilicon structures, and forming a protective cap over the recessed third polysilicon structure prior to removing the first and second polysilicon structures. In some embodiments, the first and second polysilicon structures are removed while the protective cap remains positioned over the recessed third polysilicon structure. In some embodiments, the method further includes forming a patterned mask over the third polysilicon structure, and the first and second polysilicon structures are removed while the patterned mask remains positioned over the third polysilicon structure. In some embodiments, the third polysilicon structure is between a longitudinal end of the first semiconductor fin and a longitudinal end of the second semiconductor fin. In some embodiments, after forming the first gate structure and the second gate structure, the third polysilicon structure remains positioned over the isolation region. In some embodiments, a lower portion of the third polysilicon structure has a different cross-sectional profile than an upper portion of the third polysilicon structure, and the lower portion of the third polysilicon structure has a width decreasing as a distance from the substrate increases. In some embodiments, the method further includes forming first gate spacers on opposite sidewalls of the first polysilicon structure, second gate spacers on opposite sidewalls of the second polysilicon structure, and third gate spacers on opposite sidewalls of the third polysilicon structure.

In some embodiments, a method includes following steps. A first semiconductor fin and a second semiconductor fin are formed over a substrate. A dielectric material is formed between a longitudinal end of the first semiconductor fin and a longitudinal end of the second semiconductor fin. A first sacrificial gate structure is formed across the first semiconductor fin and a second sacrificial gate structure is formed across the second semiconductor fin. An isolation structure is formed over the dielectric material. The isolation structure has opposite sidewalls between the longitudinal end of the semiconductor fin and the longitudinal end of the second semiconductor fin. A protective cap is formed over the isolation structure. With the protective cap over the isolation structure, the first sacrificial gate structure is replaced with a first gate structure and the second sacrificial gate structure is replaced with a second gate structure. In some embodiments, the isolation structure comprises a same material as the first sacrificial gate structure. In some embodiments, the isolation structure comprises polysilicon. In some embodiments, the isolation structure is recessed prior to forming the protective cap, and the first and second sacrificial gate structures are covered by a patterned mask while recessing the isolation structure. In some embodiments, forming the protective cap comprises recessing the isolation structure to form a recess over the isolation structure, depositing a dielectric layer overfilling the recess, and removing a portion of the dielectric layer outside the recess, while leaving another portion of the dielectric layer in the recess.

In some embodiments, a device includes a first semiconductor fin and a second semiconductor fin extending from a substrate, a first gate structure extending across the first semiconductor fin, a second gate structure extending across the second semiconductor fin, and an isolation structure. The isolation structure is between a longitudinal end of the first semiconductor fin and a longitudinal end of the second semiconductor fin. From a top view, the isolation structure extends parallel to the first and second gate structures and comprises a semiconductor material different than conductive materials of the first and second gate structures. In some embodiments, the polysilicon of the isolation structure has a top surface level with a top surface of the conductive material of the first gate structure. In some embodiments, the device further includes a protective cap atop the isolation structure, and the protective cap has a top surface level with a top surface of the first gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first semiconductor fin and a second semiconductor fin over a substrate;
forming an isolation region laterally surrounding a lower portion of the first semiconductor fin and a lower portion of the second semiconductor fin;
forming a first polysilicon structure across the first semiconductor fin, a second polysilicon structure across the second semiconductor fin, and a third polysilicon structure over the isolation region;
removing the first polysilicon structure and the second polysilicon structure to form a first gate trench over the first semiconductor fin and a second gate trench over the second semiconductor fin, while leaving the third polysilicon structure over the isolation region; and
forming a first gate structure in the first gate trench and a second gate structure in the second gate trench.

2. The method of claim 1, further comprising:
recessing the third polysilicon structure prior to removing the first and second polysilicon structures.

3. The method of claim 2, further comprising:
forming a protective cap over the recessed third polysilicon structure prior to removing the first and second polysilicon structures.

4. The method of claim 3, wherein the first and second polysilicon structures are removed while the protective cap remains positioned over the recessed third polysilicon structure.

5. The method of claim 1, further comprising:
forming a patterned mask over the third polysilicon structure, wherein the first and second polysilicon structures are removed while the patterned mask remains positioned over the third polysilicon structure.

6. The method of claim 1, wherein the third polysilicon structure is between a longitudinal end of the first semiconductor fin and a longitudinal end of the second semiconductor fin.

7. The method of claim 1, wherein after forming the first gate structure and the second gate structure, the third polysilicon structure remains positioned over the isolation region.

8. The method of claim 1, wherein a lower portion of the third polysilicon structure has a different cross-sectional profile than an upper portion of the third polysilicon structure.

9. The method of claim 8, wherein the lower portion of the third polysilicon structure has a width decreasing as a distance from the substrate increases.

10. The method of claim 1, further comprising:
forming first gate spacers on opposite sidewalls of the first polysilicon structure, second gate spacers on opposite sidewalls of the second polysilicon structure, and third gate spacers on opposite sidewalls of the third polysilicon structure.

11. A method comprising:
forming a first semiconductor fin and a second semiconductor fin over a substrate;
forming a dielectric material between a longitudinal end of the first semiconductor fin and a longitudinal end of the second semiconductor fin;
forming a first sacrificial gate structure across the first semiconductor fin and a second sacrificial gate structure across the second semiconductor fin;
forming an isolation structure over the dielectric material, the isolation structure having opposite sidewalls between the longitudinal end of the first semiconductor fin and the longitudinal end of the second semiconductor fin;
forming a protective cap over the isolation structure; and
with the protective cap over the isolation structure, replacing the first sacrificial gate structure with a first gate structure and the second sacrificial gate structure with a second gate structure.

12. The method of claim 11, wherein the isolation structure comprises a same material as the first sacrificial gate structure.

13. The method of claim 11, wherein the isolation structure comprises polysilicon.

14. The method of claim 11, further comprising:
recessing the isolation structure prior to forming the protective cap.

15. The method of claim 14, wherein the first and second sacrificial gate structures are covered by a patterned mask while recessing the isolation structure.

16. The method of claim 11, wherein forming the protective cap comprises:
recessing the isolation structure to form a recess over the isolation structure;
depositing a dielectric layer overfilling the recess; and
removing a portion of the dielectric layer outside the recess, while leaving another portion of the dielectric layer in the recess.

17. A device comprising:
a first semiconductor fin and a second semiconductor fin extending from a substrate;
a first gate structure extending across the first semiconductor fin;
a second gate structure extending across the second semiconductor fin; and
an isolation structure between a longitudinal end of the first semiconductor fin and a longitudinal end of the second semiconductor fin, wherein from a top view, the isolation structure extends parallel to the first and second gate structures and comprises a semiconductor material different than conductive materials of the first and second gate structures.

18. The device of claim 17, wherein the semiconductor material of the isolation structure has a top surface level with a top surface of the conductive material of the first gate structure.

19. The device of claim 17, further comprising:
a protective cap atop the isolation structure.

20. The device of claim 19, wherein the protective cap has a top surface level with a top surface of the first gate structure.
